(19) United States
(12) Patent Application Publication
(10) Pub. No.: US 2011/0108967 A1
(43) Pub. Date: May 12, 2011

(54) SEMICONDUCTOR CHIP GRID ARRAY PACKAGE AND METHOD FOR FABRICATING SAME

(75) Inventors: Zhigang BAI, Tianjin (CN); Wei Min Chen, Tianjin (CN); Zhijie Wang, Tianjin (CN)

(73) Assignee: FREESCALE SEMICONDUCTOR, INC., Austin, TX (US)

(21) Appl. No.: 12/790,999

(22) Filed: Jun. 1, 2010

(30) Foreign Application Priority Data
Nov. 10, 2009 (CN) 200910212100.X

(51) Int. Cl. H01L 23/495; H01L 21/56; H01L 23/28

(52) U.S. Cl. 257/676; 438/112; 257/E21.502; 257/E23.037; 257/E23.116

(57) ABSTRACT

A semiconductor chip grid array package includes a die attach pad and a plurality of connector pads. A semiconductor die is mounted on the die attach pad, the semiconductor die having external connection terminals electrically connected respectively to the connector pads. An encapsulating material encapsulates the die and connector pads. A stud protrudes from each of the connector pads for providing an external electrical contact for the semiconductor chip grid array package. Each of the connector pads and respective studs are formed from an electrically conductive sheet. The connector pads have a thickness of at least 60% of the thickness of the conductive sheet and the respective studs have a thickness of no more than 40% of the thickness of the conductive sheet.

### BACKGROUND OF THE INVENTION

The present invention relates generally to semiconductor packaging. More specifically, the present invention relates to a method for fabricating a semiconductor chip grid array package and a semiconductor chip grid array package that can be fabricated using such a method.

One typical type of packaged semiconductors is Quad Flat Pack (QFP) packages, which are formed with a semiconductor die mounted to a lead-frame. The lead-frame is formed from a sheet of metal that comprises a die attach pad often called a flag and arms that attach the flag to a frame. Pads on leads of the lead-frame are wire bonded to electrodes of the die to provide a means of easily electrically connecting the die to circuit boards and the like. After the electrodes and pads are wire bonded the semiconductor die and pads are encapsulated in a compound (material) such as a plastic material leaving only sections of the leads exposed. These exposed leads are cut from the frame of the lead-frame (singulated) and bent for ease of connection to a circuit board. However, the inherent structure of QFP packages results in limiting the number of leads, and therefore the number of package external electrical connections, that can be used for a specific QFP package size.

Grid array packages have been developed as an alternative to QFP packages. Grid array packages increase the number of external electrical connections while maintaining or even decreasing the package size. Such grid array packages include Pin Grid Arrays, Ball Grid Array and Land Grid Arrays. Typically, most conventional grid array packages are substrate based and are relatively expensive. Accordingly, cheaper lead-frame based grid array packages have been developed. However, because of the high density of external electrical connections of such lead-frame based grid array packages, soldering shorts may occur between adjacent external electrical connections when they are soldered to a circuit board. Further, the external electrical connections of the lead-frame based grid array packages are typically fabricated from a thin single sheet of conductive material, such as copper or aluminum, and these connections may not be sufficiently held within the encapsulating compound (material) and may become lose.

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of an electrically conductive sheet in accordance with an embodiment of the present invention;

FIG. 2 is a cross sectional view through 2-2′ of the electrically conductive sheet of FIG. 1;

FIG. 3 a cross sectional view through 2-2′ of the electrically conductive sheet of FIG. 1 after etching of channels has been performed in accordance with an embodiment of the present invention;

FIG. 4 is a cross sectional view through 2-2′ of the electrically conductive sheet after mounting a semiconductor die in accordance with an embodiment of the present invention;

FIG. 5 is a cross sectional view through 2-2′ of the electrically conductive sheet after wire bonding in accordance with an embodiment of the present invention;

FIG. 6 is a cross sectional view through 2-2′ of the electrically conductive sheet after encapsulating is performed in accordance with an embodiment of the present invention;

FIG. 7 is a cross sectional view through 2-2′ of the electrically conductive sheet after an etchant resistant material is disposed in an array on an external facing surface of the sheet in accordance with an embodiment of the present invention;

FIG. 8 is a cross sectional view through 2-2′ of the electrically conductive sheet after etching the external facing surface in accordance with an embodiment of the present invention;

FIG. 9 is an underside plan view of a semiconductor chip grid array package in accordance with an embodiment of the present invention;

FIG. 10 is a flow chart illustrating a method for fabricating the semiconductor chip grid array package of FIG. 9 in accordance with an embodiment of the present invention; and

FIG. 11 is a cross sectional view of part of a circuit board assembly that includes the semiconductor chip grid array package of FIG. 9 in accordance with an embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that package, circuit, device components and method steps that comprises a list of elements or steps does not include only those elements but may include other elements or steps not expressly listed or inherent to such package, circuit, device components or steps. An element or step proceeded by “comprises . . . a” does not, without more constraints, preclude the existence of additional identical elements or steps that comprises the element or step.

In one embodiment, the present invention provides a method for fabricating a semiconductor chip grid array package. The method comprising includes providing an electrically conductive sheet having a chip facing surface on one side and an external facing surface on the other side. Next there is conducted a process of etching channels in the chip facing surface of the electrically conductive sheet to define grid array pads in the form of a die attach pad and a plurality of connector pads. The channels are etched to a depth of at least 60% of the thickness of the conductive sheet and then there is performed a process of mounting a semiconductor die onto the die attach pad. The method then performs electrically connecting the connector pads to respective external connection terminals on the die. Next, the method performs encapsulating the die, channels and connector pads in an encapsulating material. Finally, there is performed a process of etching the external facing surface of the electrically conductive sheet to electrically isolate the grid array pads from each other. The etching the external facing surface is characterized by removing areas of the electrically conductive sheet interposed between adjacent grid array pads, and wherein the etching the external facing surface provides a stud protruding from each of the connector pads.

In another embodiment, the present invention provides a semiconductor chip grid array package that includes a die attach pad and a plurality of connector pads. The semiconductor chip grid array package has a semiconductor die mounted onto the die attach pad, the semiconductor die having external connection terminals electrically connected respectively to the connector pads. There is an encapsulating material that encapsulates the die and connector pads. A stud protrudes from each of the connector pads for providing an external electrical contact for the semiconductor chip grid array package. Each of the connector pads and respective studs are formed from an electrically conductive sheet. The connector pads are of a thickness of at least 60% of the thickness of the conductive sheet and the respective studs are of a thickness of no more than 40% of the thickness of the conductive sheet.

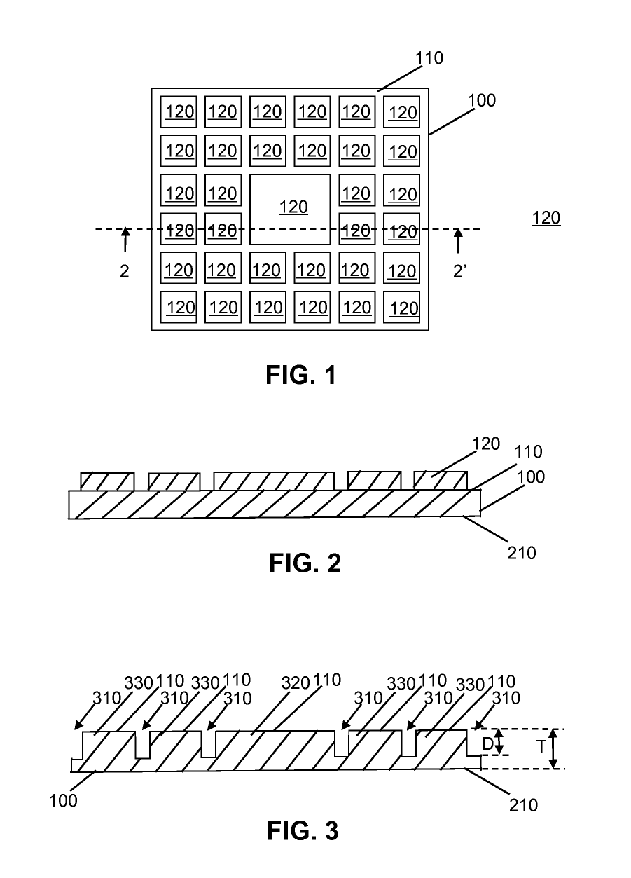

Referring to FIGS. 1 and 2 there is illustrated a plan view of an electrically conductive sheet 100 and a cross sectional view through 2-2′ of an electrically conductive sheet 100. The electrically conductive sheet 100 is provided in a first step of a method for fabricating a semiconductor chip grid array package. The electrically conductive sheet 100 is typically made from copper, aluminum or any other suitable material as will be apparent to a person skilled in the art. There is a chip facing surface 110 on one side of the electrically conductive sheet 100 and an external facing surface 210 is on the other side of the electrically conductive sheet 100. As shown, the there is an etchant resistant material 120 disposed in an array on the chip facing surface 110 of the electrically conductive sheet 100.

Referring to FIG. 3, there is illustrated a cross sectional view through 2-2′ of the electrically conductive sheet 100 after etching of channels 310 has been performed in the chip facing surface 110. The etching of channels 310 define grid array pads GPs in the form of a die attach pad 320 and a plurality of connector pads 330. These channels 310 are etched to a depth D of at least 60% of the thickness T of the conductive sheet 100. However, in another embodiment the channels 310 are etched to a depth D of at least 70% of the thickness T of the conductive sheet 100. Also, in yet a further embodiment, the channels 310 are etched to a depth D of between 70% to 80% of the thickness T of the conductive sheet 100.

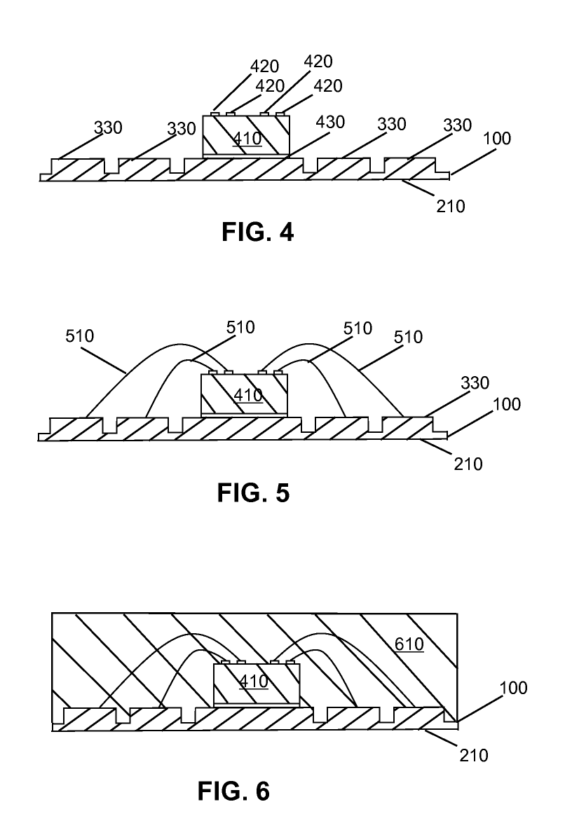

Referring to FIG. 4, there is illustrated a cross sectional view through 2-2′ of the electrically conductive sheet 100 after mounting a semiconductor die 410 onto the die attach pad 320 has been performed. The semiconductor die 410 has external connection terminals 420 on a top surface and the bottom surface is bonded to the die attach pad 320 by a cured epoxy resin 430, however solder paste or double sided tape can be used as alternative means for bonding.

Referring to FIG. 5, there is illustrated a cross sectional view through 2-2′ of the electrically conductive sheet 100 after connecting the connector pads 330 to respective external connection terminals 420 on the die 410 has been performed. The electrical connecting is typically performed by wire bonding gold wires 510 between the connector pads 330 and the respective external connection terminals 420.

In FIG. 6, there is illustrated a cross sectional view through 2-2′ of the electrically conductive sheet 100 after encapsulating the die 410, channels 310 and connector pads 330 in an encapsulating material 610. This encapsulating material 610 is an electrically insulting material, generally plastics, that is typically molded to the electrically conductive sheet 100.

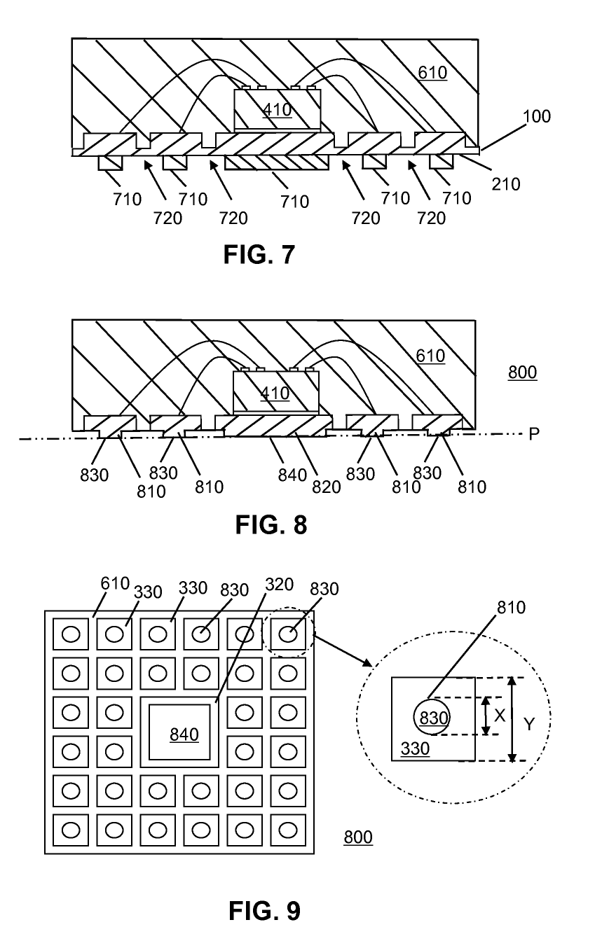

Shown in FIG. 7 is a cross sectional view through 2-2′ of the electrically conductive sheet 100 after an etchant resistant material 710 is disposed in an array on the external facing surface 210 of the electrically conductive sheet 100. The etchant resistant material 710 is located so that its exposes etchant to areas 720 of the electrically conductive sheet 100 that are interposed between adjacent grid array pads (GPs).

In FIG. 8, there is illustrated a cross sectional view of through 2-2′ of the electrically conductive sheet 100 after etching the external facing surface 210 of the electrically conductive sheet 100 to electrically isolate the grid array pads GPs from each other. More specifically, the etching of the external facing surface 210 removes the areas 720 of the electrically conductive sheet interposed between adjacent grid array pads (GPs). After the etching of the external facing surface 210, fabrication of the semiconductor chip grid array package 800 is essentially completed. The etching of the external facing surface 210 provides the semiconductor chip grid array package 800 with a stud 810 protruding from each of the connector pads 330 and an external mount 820 extending from the die attach pad 320. Ideally, and as shown, each stud has a mounting surface 830 that is planar (in a plane P) with a mounting surface 840 of the external mount 820.

It will be apparent to a person skilled in the art that if the channels 310 are etched to a depth D of at least 60% of the thickness T of the conductive sheet 100, then each stud 810 will have a depth of no more than 40% of the thickness of the conductive sheet. Similarly, if the channels 310 are etched to a depth D of at least 70% of the thickness T of the conductive sheet 100, then each stud 810 will have a depth of no more than 30% of the thickness of the conductive sheet 100. Further, if the channels 310 are etched to a depth D of between 70% to 80% of the thickness T of the conductive sheet 100, then each stud 810 will a depth of between 20% to 30% of the thickness of the conductive sheet 100.

Referring to FIG. 9 there is illustrated an underside plan view of the semiconductor chip grid array package 800. As shown, the stud 810 protruding from each of the connector pads 330 is a rod R having a circular cross section. This rod R has a maximum diameter X that is at least 30% smaller than a maximum width Y of the connector pad 330 from which it protrudes. It is envisaged that the stud may be general, the stud 810 protruding from each of the connector pads 330 may be other than a rod with a circular cross section. Accordingly, as a general rule the stud 810 has a maximum width that is at least 30% smaller than a maximum width of the connector pad from which it protrudes.

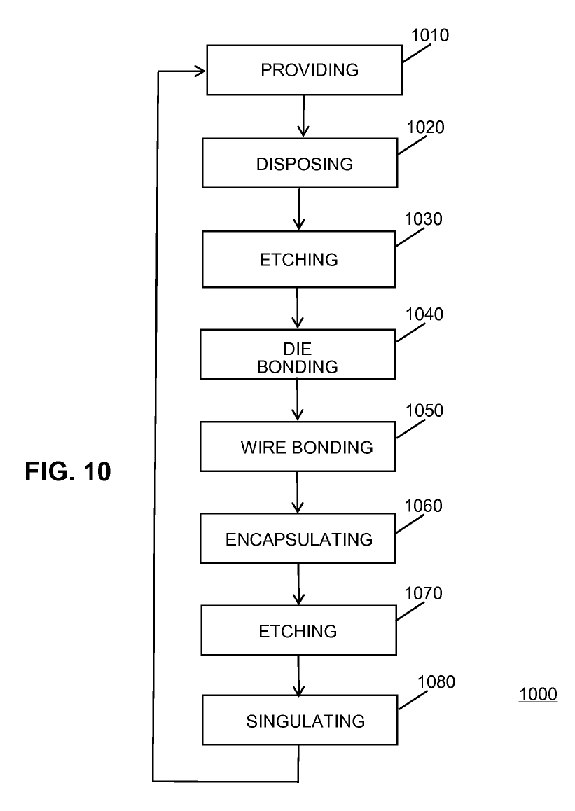

FIG. 10 is a flow chart summarizing the method 1000 for fabricating the semiconductor chip grid array package 800 as performed by the above steps mainly described with reference to FIGS. 1-8. At a providing step 1010 there is provided the electrically conductive sheet 100. Typically, the electrically conductive sheet 100 is of sufficient size to allow for the fabricating of numerous semiconductor chip grid array packages 800. However, for ease of illustration, only the fabrication of one semiconductor chip grid array package 800 has been illustrated above and will be described by the method 1000.

Disposing an etchant resistive material 120 on the chip facing surface of the electrically conductive sheet is 100 is performed at a disposing step 1020 and an etching process 1030 defines the grid array pads GPs in the form of the die attach pad 320 and the connector pads 330.

A mounting or die bonding process 1040 then mounts the semiconductor die 410 onto the die attach pad 320 and a wire bonding process 1050 performs electrically connecting the connector pads 330 to the respective external connection terminals on the die semiconductor die 420. Next, the semiconductor die 410 is encapsulated by an encapsulating process 1060 and an etchant resistant material 710 is then disposed in an array on the external facing surface 210 at disposing step 1040. An etching process 1070 then performs etching the external facing surface 210 of the electrically conductive sheet 100 to electrically isolate the grid array pads GPs from each other. As mentioned above, typically the electrically conductive sheet 100 is of sufficient size to allow for the fabricating of numerous semiconductor chip grid array packages 800. Thus, a singulating process 1080, performed by sawing, may be required to singulate (separate) the semiconductor chip grid array package 800 from other semiconductor chip grid array packages fabricated on the electrically conductive sheet 100. The method 1000 then returns to providing step 1010 and is repeated on electrically conductive sheet 100.

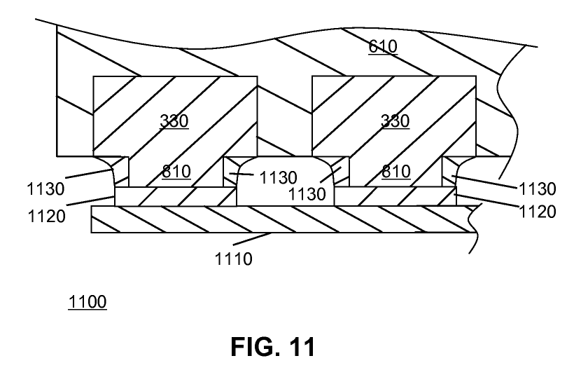

Referring to FIG. 11 there is illustrated a cross sectional view of part of a circuit board assembly 1100 that includes the semiconductor chip grid array package 800. For ease of illustration, only part of the chip grid array package 800 is shown. The circuit board assembly 1100 has a circuit board substrate 1110 with solder pads 1120 and associated runners (not shown). The studs 810 have been soldered to a respective one of the solder pads 1120 by a solder 1130. As shown, due to a surface tension effect on the solder 1130 (when in a molten state during soldering), the solder 1130 tends to be attracted to an underside of its associated connector pad 330. As a result of this surface tension effect, the possibility of the solder 1130 shorting between adjacent solder pads 1120 is reduced.

Advantageously, the present invention provides a chip grid array package that can facilitate an increased number of external electrical connections (studs 810) when compared with most similar sized conventional QFP packages. Also, the present invention reduces the possibility of soldering shorts between adjacent studs 810 when they are soldered to a circuit board due to the above-mentioned surface tension effect. Furthermore, since the channels 310 are etched to a depth D of at least 60% of the thickness T of the conductive sheet 100, a relative greater surface area of the connector pads 330 can bond to the encapsulating material 610. This relative greater surface area of the connector pads 330 therefore reduces the possibility of the connector pads 330 becoming loose in the encapsulating material 610.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A method for fabricating a semiconductor chip grid array package, the method comprising:
providing an electrically conductive sheet having a chip facing surface on one side and an external facing surface on the other side;
etching channels in the chip facing surface of the electrically conductive sheet to define grid array pads in the form of a die attach pad and a plurality of connector pads, wherein the channels are etched to a depth of at least 60% of the thickness of the conductive sheet;
mounting a semiconductor die onto the die attach pad;
electrically connecting the connector pads to respective external connection terminals on the die;
encapsulating the die, channels and connector pads in an encapsulating material; and
etching the external facing surface of the electrically conductive sheet to electrically isolate the grid array pads from each other, wherein the etching the external facing surface is characterized by removing areas of the electrically conductive sheet interposed between adjacent grid array pads, and wherein the etching the external facing surface forms a stud protruding from each of the connector pads.

2. The method for fabricating a semiconductor chip grid array package of claim 1, wherein the die attach pad has an external mounting surface planar with mounting surfaces of each said stud protruding from each of the connector pads.

3. The method for fabricating a semiconductor chip grid array package of claim 1, wherein the channels are etched to a depth of at least 70% of the thickness of the conductive sheet.

4. The method for fabricating a semiconductor chip grid array package of claim 3, wherein the channels are etched to a depth of between 70% to 80% of the thickness of the conductive sheet.

5. The method for fabricating a semiconductor chip grid array package of claim 1, wherein the stud has a depth of no more than 40% of the thickness of the conductive sheet.

6. The method for fabricating a semiconductor chip grid array package of claim 5, wherein the stud has a depth of no more than 30% of the thickness of the conductive sheet.

7. The method for fabricating a semiconductor chip grid array package of claim 6, wherein the stud has a depth of between 20% to 30% of the thickness of the conductive sheet.

8. The method for fabricating a semiconductor chip grid array package of claim 1, wherein the electrically connecting is performed by wire bonding.

9. The method for fabricating a semiconductor chip grid array package of claim 1, wherein the stud has a maximum width that is at least 30% smaller than a maximum width of the connector pad from which it protrudes.

10. The method for fabricating a semiconductor chip grid array package of claim 1, wherein the stud protruding from each of the connector pads is a rod having a circular cross section.

11. The method for fabricating a semiconductor chip grid array package of claim 10, wherein the rod has a maximum diameter that is at least 30% smaller than a maximum width of the connector pad from which it protrudes.

12. The method for fabricating a semiconductor chip grid array package of claim 1, wherein the electrically conductive sheet is of sufficient size to allow for the fabricating of numerous semiconductor chip grid array packages, and the method includes a further step of singulating the semiconductor chip grid array package from other semiconductor chip grid array packages fabricated on the electrically conductive sheet.

13. A semiconductor chip grid array package comprising:
a die attach pad and a plurality of connector pads;
a semiconductor die mounted on the die attach pad, the semiconductor die having external connection terminals electrically connected respectively to the connector pads;
an encapsulating material that encapsulates the die and connector pads;
a stud protruding from each of the connector pads for providing an external electrical contact for the semiconductor chip grid array package, wherein each of the connector pads and respective studs are formed from an electrically conductive sheet, and the connector pads are of a thickness of at least 60% of the thickness of the conductive sheet and the respective studs are of a thickness of no more than 40% of the thickness of the conductive sheet.

14. The semiconductor chip grid array package of claim 13, wherein the die attach pad has an external mounting surface planar with mounting surfaces of each stud protruding from each of the connector pads.

15. The semiconductor chip grid array package of claim 13, wherein the connector pads have a thickness of at least 70% of the thickness of the conductive sheet and the respective studs have a thickness of no more than 30% of the thickness of the conductive sheet.

16. The semiconductor chip grid array package of claim 13, wherein the connector pads have a thickness of between 70% to 80% of the thickness of the conductive sheet and the respective studs have a thickness of between 20% to 30% of the thickness of the conductive sheet.

17. The semiconductor chip grid array package of claim 13, wherein the stud protruding from each of the connector pads is a rod having a circular cross section.

18. The semiconductor chip grid array package of claim 13, wherein the stud has a maximum width that is at least 30% smaller than a maximum width of the connector pad from which it protrudes.

19. The semiconductor chip grid array package of claim 17, wherein the rod has a maximum diameter that is at least 30% smaller than a maximum width of the connector pad from which it protrudes.
